(19) United States
(12) Patent Application Publication
(10) Pub. No.: US 2011/0316386 A1
(43) Pub. Date: Dec. 29, 2011

(54) MICRORESONATOR, RESONATOR SENSOR WITH SUCH MICRORESONATOR, AND SENSOR ARRAY COMPRISING AT LEAST TWO SUCH MICRORESONATORS

(75) Inventors: Koray Karakaya, Eindhoven (NL); Mercedes Crego Crego Calama, Geldrop-Mierlo (NL); Sywert H. Brongersma, Eindhoven (NL)

(73) Assignee: Stichting IMEC Nederland, Eindhoven (NL)

(21) Appl. No.: 13/162,504

(22) Filed: Jun. 16, 2011

Related U.S. Application Data
(60) Provisional application No. 61/356,962, filed on Jun. 21, 2010.

(30) Foreign Application Priority Data
Jun. 18, 2010 (EP) 10166529.7

(51) Int. Cl. H01L 41/107; G01R 31/28; H02N 1/08; H01L 41/04; H02K 37/00

(52) U.S. Cl. 310/318; 310/323.21; 310/25; 310/300; 29/593

(57) ABSTRACT

A microresonator for use as a resonator in a detector is disclosed. In one aspect, the microresonator has a first predetermined resonance mode. The microresonator has an integrated electronic transducer for measuring deformation of the microresonator in the first predetermined resonance mode of the microresonator. The transducer is located at a local deformation of the predetermined resonance mode to measure the deformation of the microresonator at such location. The first predetermined resonance mode may be one of higher order resonance modes.

### CROSS REFERENCE TO RELATED APPLICATIONS

This application claims priority under 35 U.S.C. §119(e) to U.S. provisional patent application 61/356,962 filed on Jun. 21, 2010, which application is hereby incorporated by reference in its entirety.

### BACKGROUND OF THE INVENTION

1. Field of the Invention

The disclosed technology relates to a microresonator for use as a resonator in sensing applications, to a resonator sensor comprising such microresonator, and to a sensor array comprising at least two such microresonators.

2. Description of the Related Technology

It is known to use microcantilevers in sensing applications, e.g. chemical and biological sensing applications. Such microcantilevers can have two operation modes, i.e. a static mode and a dynamic or resonant mode. In a resonant mode, an analysis is performed by monitoring resonance frequency shifts (e.g. induced by an analyte) of the resonating microcantilever or of a microresonator of any kind.

The resonance frequency of a microresonator (ω₀) is a function of the microresonator stiffness (k₀) and mass (m₀). Therefore any change in the mass (Δm/m₀) (for example: by precipitation, binding, absorption/adsorption, desorption, evaporation, deposition, etc.), as well as a change of the microresonator stiffness (Δk/k₀), cause a shift in the resonance frequency (Δω/ω₀). Binding of specific molecules, atoms, particles, organic cells, etc. on the resonating structure can be monitored by monitoring the resonance frequency of the microresonator. Therefore, such microresonators are useful in sensing applications.

Resonant structures, such as e.g. cantilevers, bridges or membranes, have a number of resonance vibration modes called ‘mode shapes’. Each mode shape has a specific deformation pattern of the resonating structure at a particular frequency, depending on the properties of the resonating structure. At each mode shape of a given resonator, localized deformations on various positions of the structure can be observed, such as for example local maxima and minima. For example, for resonant microcantilevers, beams and membranes, different mode shapes cause localized deformations on various positions of the resonating structure.

Increased mass sensitivity of resonant sensors at higher order resonance modes has been reported. It has been shown, both theoretically and experimentally, that the sensitivity of a cantilever-based mass sensor to a point mass can be higher for higher-order resonance modes than for the fundamental or first mode shape. It has been shown that also for vibrating cantilevers with a distributed mass load, the change in resonance frequency (and thus the sensitivity) increases with increasing mode number.

There are two major approaches for electrical transduction of deformations of a resonating structure with integrated, for example electronic, transducers: a first approach is using for example piezoelectric or piezoresistive transducers, wherein an electrical signal is generated by deformation of the transducers integrated with the resonating structure. In a second approach, for example with capacitive or magnetic transducers, relative displacement of the resonating body against a counterpart (e.g. the counter electrode for electrostatic detection, permanent magnet and/or coils for magnetic detection, etc.) is used for monitoring the movement of a resonating structure.

In “Laser vibrometry and impedance characterization of piezoelectric microcantilevers”, J. Micromech. Microeng., 17 (2007) 931-937 by P Sanz, J Hernando, J Vazquez and J L Sánchez-Rojas, which is incorporated herein by reference in its entirety, the frequency response of microcantilevers above the first resonance mode is further described. The vibration response of a ZnO-based piezoelectric cantilever is studied for seven resonance modes. Herein, the microcantilever consists of a piezoelectric ZnO layer between two Ti/Au metal electrodes covering the entire surface of a non-piezoelectric silicon supporting layer. The frequencies and the mode shape of the first seven resonances of the cantilever are measured by laser vibrometry. In addition, an impedance analysis of the first seven resonances is also performed. It is observed that higher-order resonance modes have relatively low displacement as measured optically. Moreover, they also showed lower signal amplitude as measured through the transducer by impedance analysis. Some higher-order resonance modes, for example the fifth and the second, were even only detectable optically (by using a laser Doppler interferometer) and showed null response during impedance analysis, due to the deformation pattern of these mode shapes featuring an anti-symmetric torsional component and the subsequent compensation of the piezoelectrically generated charges generated under simultaneous presence of tensile and compressively strained regions of the piezoelectric stack.

Although the sensitivity of resonating microcantilevers increases at higher resonance modes, the signal amplitude generated by the transducer is generally lower than the signal acquired at lower resonance modes, because absolute physical displacement decreases for higher-order resonance modes. Therefore achieving a good signal-to-noise ratio becomes more difficult at high resonance modes. In addition to that, inhomogeneous or even anti-symmetric deformation of the resonator at higher order resonance modes causes degradation or even total loss of the signal as described in previous paragraph. For example, when using a piezoelectric transducer covering a substantial part of the surface of a microcantilever, inhomogeneous or even anti-symmetric deformation of the cantilever leads to charge neutralization between tensile and compressive strained areas and thus to a decreased signal amplitude. Therefore, it is not efficiently possible, or for some cases not even possible at all, with the known methods to efficiently measure deformation of the microresonator with an integrated transducer, without having to use additional bulky equipment such as for example a Doppler interferometer.

### SUMMARY OF CERTAIN INVENTIVE ASPECTS

Certain inventive aspects relate to a microresonator comprising at least one integrated transducer with which it is possible to efficiently measure deformation of the microresonator in at least one predetermined resonance mode of the microresonator, such as for example a resonance mode with an inhomogeneous deformation of the microresonator.

Thereto, the at least one integrated transducer is provided at the location of a local deformation, preferably a single local extremum in deformation, of the at least one predetermined resonance mode to measure the deformation of the microresonator at the location of the local deformation, e.g. local extremum. The at least one predetermined resonance mode can be one of the higher order resonance modes.

Since the transducer is located at the location of a local deformation, e.g. a local extremum, an accurate measurement of the deformation of the microresonator, e.g. at the local extremum, is possible, even for resonance modes with an inhomogeneous deformation, especially when the transducer is located at the location of a single local deformation. For example, in such a configuration charge neutralization between tensile and compressive strained areas can be avoided as the transducer is now located at the location of a local deformation and preferably a single local deformation. In such case other local deformations have no or very limited influence on the measurement of the deformation of the microresonator.

As the transducer is integrated with the microresonator, this avoids the need for bulky equipment but nevertheless allows an efficient measurement of the deformation of the microresonator in the predetermined resonance mode of the microresonator. Since higher-order resonance modes, i.e. resonance modes of at least the second order resonance mode, can be measured more efficiently without having to use additional bulky equipment such as for example Doppler interferometers, sensing applications, such as resonator sensors, using the microresonator can also be made more compact.

In some embodiments of the microresonator according to the present invention, the microresonator comprises a first integrated electronic transducer for measuring deformation of the microresonator in a first predetermined resonance mode and a second integrated electronic transducer for measuring deformation of the microresonator in a second predetermined resonance mode of the microresonator, the first transducer being provided at the location of a first local deformation, e.g. first local extremum in deformation, of the first predetermined resonance mode and the second transducer being provided at the location of a second different local deformation, preferably a second local extremum in deformation, of the second predetermined resonance mode.

Since the first transducer and the second transducer are located at the location of a first local deformation, e.g. a first local extremum, and a second local deformation, e.g. second local extremum, respectively, an accurate measurement of the deformation of the microresonator, e.g. at the first local extremum in a first predetermined resonance mode and at the second local extremum in a second predetermined resonance mode, is possible, even for resonance modes with an inhomogeneous deformation.

As both transducers are integrated with the microresonator, this leads to less bulky equipment but nevertheless allows an efficient measurement of the deformation of the microresonator in the predetermined resonance modes of the microresonator.

Such a microresonator allows a more precise measurement at the predetermined resonance modes of the microresonator and therefore, for example, allows a more precise measurement of a frequency shift due to a change of mass and/or stiffness of the microresonator. This allows measuring relatively small changes in the mass and/or the thickness of the microresonator.

With such microresonators comprising a first transducer and a second transducer, it becomes for example possible to use a single microresonator in sensor applications with multiple sensitivity scale operations. For example, the second resonance mode can be of a lower order than the first resonance mode, corresponding to lower resonance frequencies which can for example be used for a low sensitivity scale, i.e. a rough analysis, whereas the first resonance mode can for example be used for a higher order resonance mode at a higher frequency for a more sensitive scale, i.e. a finer analysis. However, the second resonance mode can also equal the first resonance mode in which case the microresonator can for example be used for more accurate measurements of the deformation of the microresonator.

The first predetermined resonance mode in other words can be any one of the resonance modes of the microresonator from the second order resonance mode upwards, such as for example the second order, the third order, the fourth order, the fifth order, the sixth order, the seventh order, the eighth order, the ninth order, the tenth order, the eleventh order the twelfth, order the thirteenth order, etc. resonance mode of the microresonator.

The second predetermined resonance mode in other words can be any one of the resonance modes of the microresonator from the first order resonance mode upwards, such as for example the first order, the second order, the third order, the fourth order, the fifth order, the sixth order, the seventh order, the eighth order, the ninth order, the tenth order, the eleventh order, the twelfth order, the thirteenth order, etc. resonance mode of the microresonator.

As indicated above, in some embodiments of the microresonator according to the present invention, the first and/or second local deformation preferably is a local extremum in deformation of the corresponding predetermined resonance mode. It has been found that when the first and/or second local deformation is a local extremum, respectively called first local extremum and second local extremum, the signal to noise ratio further increases due to the relatively large local deformation of the microresonator. The number of individual transducers present on the resonator can be selected depending on the number of predetermined resonance modes and their mode shapes, actuation requirements and can be as many as required.

In some embodiments of the microresonator according to the present invention, the respective transducers comprise a respective layer of piezoelectric material sandwiched between two respective measuring electrodes. Alternatively, the respective transducers comprise a respective layer of piezoelectric material with respective interdigitated electrodes at one side of the layer of piezoelectric material. Such transducers are relatively easy to fabricate and allow a relatively precise measurement of the deformation of the microresonator at the first and the second location while being relatively robust and far less bulky than, for example, Doppler interferometers. In some embodiments of the microresonator according to the present invention, the piezoelectric material is chosen from the group of for example ZnO, PZT (lead zirconate titanate, (Pb[ZrₓTi₁₋ₓ]O₃ with 0<x<1) possibly with dopants), and AIN (aluminum nitride). In another embodiment, the resonator itself can be at least part of the piezoelectric transducer, e.g. a piezoelectric semiconductor can be used as a structural material.

Piezoelectric transducers integrated with the resonator can be fabricated using a single material combination for all transducers. However, in one embodiment, if a transducer is used specifically for actuation of the resonator, then this can be fabricated with a material combination with better actuation characteristics. In addition to that, transducers used for sensing the deformation of the resonator, can be fabricated with the materials that have better sensing characteristics. Selecting the suitable piezoelectric material for aforementioned sensing and actuating transducers can be done for example by a figure-of-merit defined for actuation and for sensing. For example, PZT has a relatively large voltage-to-mechanical conversion capability and is therefore very suitable for use in an actuator. For example, AIN has relatively good signal amplitude and has a relatively good signal-to-noise ratio. Therefore it is very suitable for use in a sensor. Thus, a transducer used for actuation can advantageously be fabricated using PZT as a piezoelectric material with good actuation characteristics, whereas AlN can advantageously be used as the piezoelectric material in a sensing transducer, for transducing deformations to electric signals.

Other types of transduction mechanisms, such as electrostatic (capacitive), electromagnetic, piezoresistive, electrooptic, etc., can also be used for transducing the deformations of the resonator into electrical signals. A combination of these transducer types can also be used together, for example piezoelectric and electrostatic, piezoelectric and piezoresistive, piezoresistive and electrostatic, piezoelectric and electromagnetic, electrostatic and electrooptic, etc.

In some embodiments of the microresonator according to the present invention, the microresonator may comprise a geometrical irregularity, such as for example a protrusion extending from the remainder of the microresonator, e.g. for manipulating the amplitude of a predetermined local deformation. Such a protrusion may help generating relatively large local deformations of the microresonator for some of the resonance modes. A combination of multiple transducers placed for capturing these relatively large deformations can lead to a better signal-to-noise ratio and the measurement of the resonance mode can be made even more precise for selected resonance modes.

One inventive aspect relates to a resonator sensor comprising a microresonator.

One inventive aspect relates to a sensor array comprising at least two microresonators, each of the microresonators having different resonance modes. Such a configuration for example allows a simultaneous measurement with different microresonators having substantially the same physical/chemical interactions with their surroundings but substantially operating in different resonance modes such that simultaneous measurements with different accuracies are obtained. The at least two microresonators can have a same geometry with different dimensions, for example for enhancing the resonance frequency coverage. The at least two microresonators can have different geometries, for example different geometries with a same surface area where mass loading can occur such as to obtain comparable measurements with the different microresonators.

Microresonators with different geometries can also be used for manipulating a particular mode shape of a predefined resonance mode. At least two microresonators with a first microresonator comprising a first transducer type, for example, piezoelectric, piezoresistive, electrostatic, electromagnetic, etc., and a second microresonator comprising another transducer type can also form an array. Any possible combination of different transducers with different transduction mechanisms can be present in a resonator array.

One inventive aspect relates to a method for making a microresonator, the method comprising analyzing at least one resonance mode of a microresonator, for example by calculating or numerically modeling a model for the microresonator, finding at least one location of the microresonator comprising a local deformation, preferably a local extremum, of the analyzed resonance mode and integrating an electronic transducer with the microresonator for measuring deformation of the microresonator at the location.

Certain objects and advantages of various inventive aspects have been described herein above. Of course, it is to be understood that not necessarily all such objects or advantages may be achieved in accordance with any particular embodiment of the invention. Thus, for example. those skilled in the art will recognize that the invention may be embodied or carried out in a manner that achieves or optimizes one advantage or group of advantages as taught herein without necessarily achieving other objects or advantages as may be taught or suggested herein. Further, it is understood that this summary is merely an example and is not intended to limit the scope of the invention as claimed. The invention, both as to organization and method of operation, together with features and advantages thereof, may best be understood by reference to the following detailed description when read in conjunction with the accompanying drawings.

### BRIEF DESCRIPTION OF THE DRAWINGS

The invention will be further elucidated by means of the following description and the appended figures.

FIG. 1(a) shows an overview of a first embodiment of a microresonator.

FIG. 1(b) shows a top view of the microresonator of FIG. 1(a).

FIG. 1(c) shows a cross-section of a detail of FIG. 1(b).

FIG. 2 shows an overview of a second embodiment of a microresonator.

FIG. 3 shows an overview of a third embodiment of a microresonator.

FIG. 4(a) shows an overview and FIG. 4(b) shows a top view of a fourth embodiment of a microresonator.

FIG. 5 shows a top view of different embodiments of a microresonator.

FIG. 6 shows a top view of one embodiment of a microresonator.

FIG. 7 shows the impedance spectrum for a microcantilever with a single transducer and for a microcantilever with two transducers.

FIG. 8 and FIG. 9 show impedance spectra for microcantilevers with two transducers in accordance with one embodiment.

Any reference signs in the claims shall not be construed as limiting the scope of the present disclosure.

In the different drawings, the same reference signs refer to the same or analogous elements.

### DETAILED DESCRIPTION OF CERTAIN ILLUSTRATIVE EMBODIMENTS

The present invention will be described with respect to particular embodiments and with reference to certain drawings but the invention is not limited thereto. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the invention.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein. Moreover, the terms top, bottom, over, under and the like in the description are used for descriptive purposes and not necessarily for describing relative positions. The terms so used are interchangeable under appropriate circumstances and the embodiments of the invention described herein can operate in other orientations than described or illustrated herein.

The term “comprising” should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

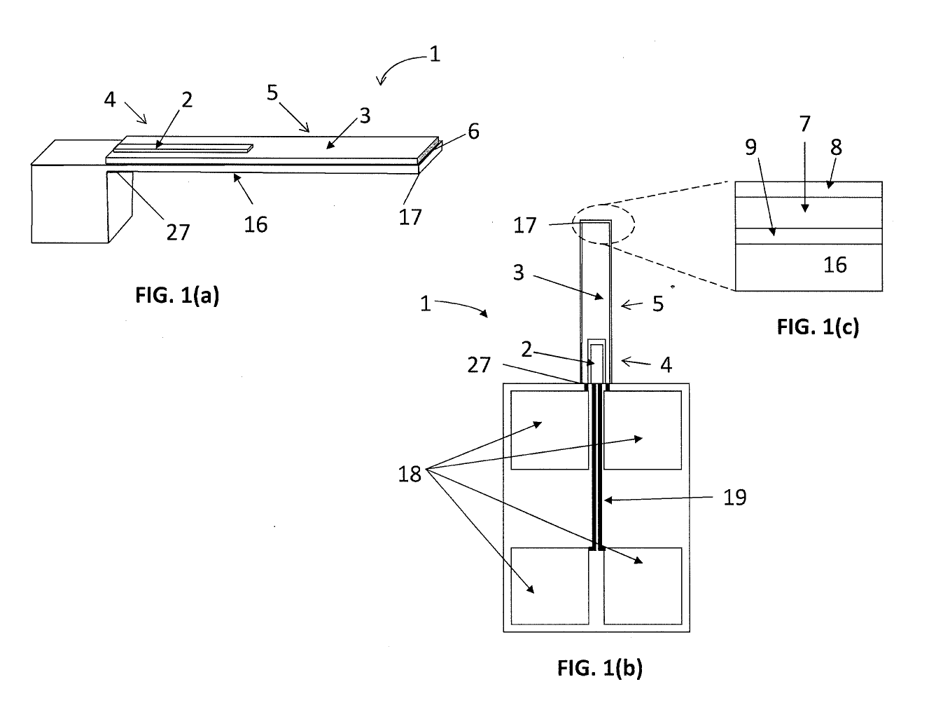

FIG. 1(a) and FIG. 1(b) show a first embodiment of a microresonator 1. The microresonator 1 is provided for use as a resonator in a sensor or a detector, for example a mass absorption, desorption, adsorption, physi-/chemisorption detector or a detector for detecting a change in the surface stress gradient or stress gradient within the resonator in general, achieved by stiffening or softening of one of the materials of the resonator structure, formation of an additional layer (e.g. a biomolecule layer) on the resonator, or chemical reactions occurring on and/or around the resonator causing local temperature changes (i.e. by exothermic or endothermic reactions, by evaporation of a volatile reaction product, etc.). The sensitivity obtained with such a resonator for example lies with the range of between femtograms and grams.

The microresonator 1 is provided for resonating in a first predetermined resonance mode. The first predetermined resonance mode is one of the higher order resonance modes. The first resonance mode in other words can be any one of the resonance modes of the microresonator from the second order resonance mode upwards, such as for example the second order, the third order, the fourth order, the fifth order, the sixth order, the seventh order, the eighth order, the ninth order, the tenth order, the eleventh order, the twelfth order, the thirteenth order, etc. resonance mode of the microresonator.

The microresonator 1 shown in the figures is based on a cantilever structure. This is however not critical for the invention and the microresonator 1 can for example also be a bridge (clamped-clamped beam), a cross-shaped structure, a H-shaped structure, or a membrane or any other type of resonator design in the micrometer and/or nanometer range. Therefore one embodiment covers cantilevers, doubly clamped beams, membranes or any possible form of a resonator in the micrometer and/or nanometer range. Cantilevers are however preferred as they present a relatively large deformation as compared to, for example, doubly clamped beams, and membranes, and moreover are relatively easy to make.

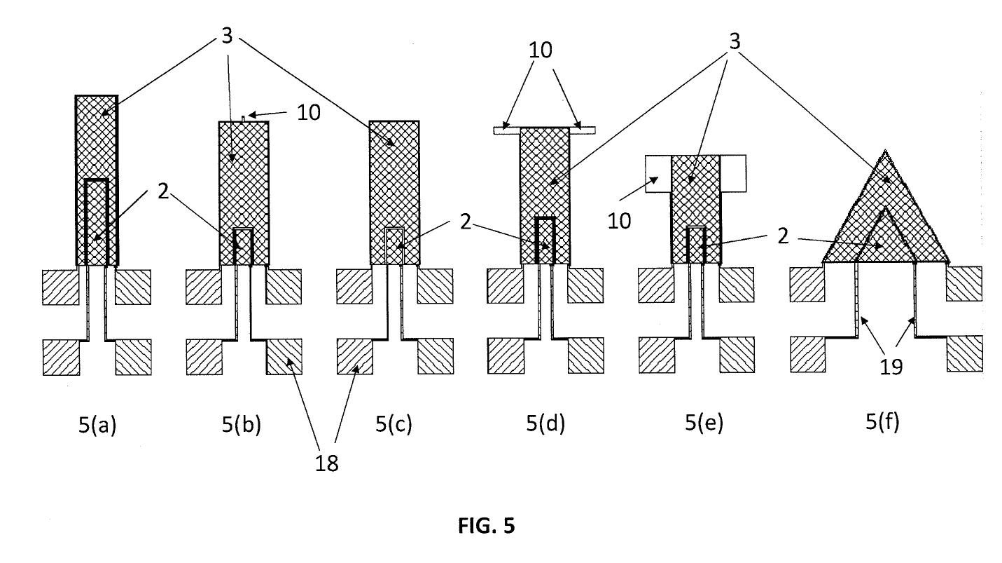

The microresonator 1 comprises a transducer 2 at a predetermined location, taking into account the predetermined resonance mode, on the surface 6 of the cantilever. The microcantilever 1 shown in FIG. 1(a) comprises a beam 16 clamped at one longitudinal end 27 and being free to vibrate at an opposing end 17. However other shapes are possible as for example is shown in FIG. 5.

The surface 6 of the microresonator 1 shown in the figures is substantially planar when the microresonator 1 is not vibrating. Moreover, the microresonator 1 has substantially a uniform thickness. This is however not critical for the invention and the surface 6 and the thickness of the microresonator 1 can be selected in function of the desired characteristics of the microresonator 1.

The shown microresonator 1 comprises an electronic transducer 2 positioned along its surface 6 for measuring deformation of the microresonator 1 in the first predetermined resonance mode of the microresonator 1. However, any other way of integrating the transducer 2 is possible. For example, the electronic transducer 2 can be provided in the interior of the microresonator 1, for example fully covered by other materials and/or components of the microresonator 1.

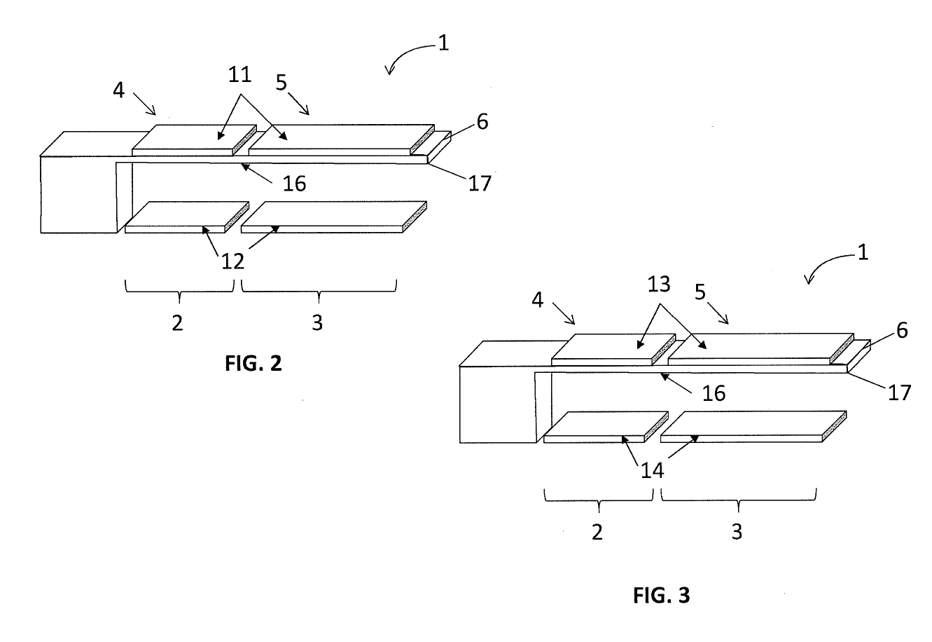

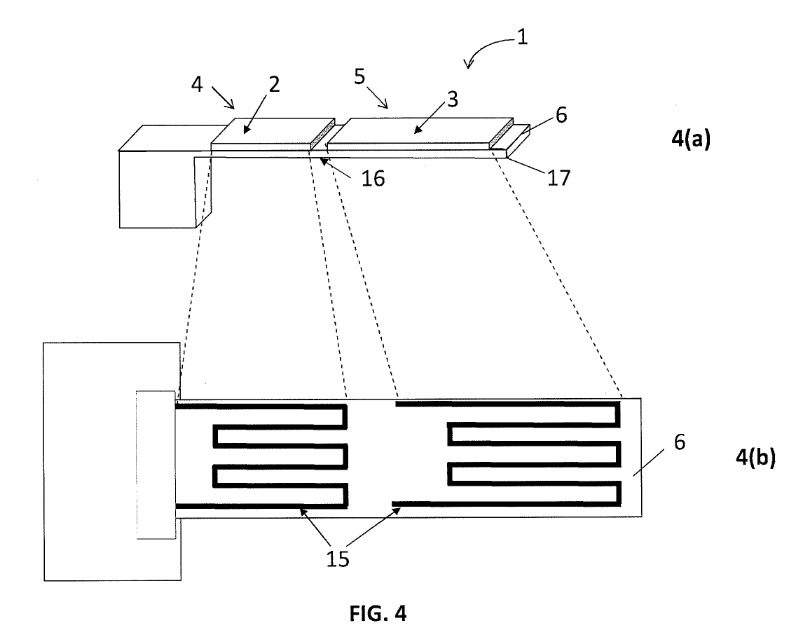

The electronic transducer 2 shown in FIG. 1(a) and FIG. 1(b) is a piezoelectric transducer 2. However, also other transducers are possible as shown in FIG. 2, FIG. 3 and FIG. 4 in which the transducer 2 respectively is a capacitive transducer, magnetic transducer and a piezoresistive transducer. However, other transducers, although not shown, are also possible.

The first transducer 2 is substantially provided at the location of a local deformation 4 of the predetermined resonance mode, more specifically a single local deformation 4, to measure the deformation of the microresonator at the location of the local deformation 4. Especially local deformations of resonance modes due to their shape featuring inhomogeneous deformation resulting in stress of opposite sign on the surface 6 are detectable using the transducer 2 at such a location. Also, as explained above, the location of the local deformation 4 preferably is a local extremum in deformation of the predetermined resonance mode. This is however not shown in the figures and the figures only show a schematic overview of the microresonator.

FIG. 1(a) and FIG. 1(b) further show a second electronic transducer 3 positioned along the cantilever surface 6 for measuring deformation of the microresonator 1 in a second predetermined resonance mode of the microresonator. However, any other way of integrating the transducer 3 is possible. For example, the electronic transducer 3 can be provided in the interior of the microresonator 1, for example fully, covered by other materials and/or components of the microresonator 1. The second transducer 3 is preferably substantially provided at the location of a second different local deformation 5 of the second predetermined resonance mode, more specifically a single local deformation 5, to measure the deformation of the microresonator 1 at the location of the second local deformation 5.

Dynamic operation of a microresonator 1 of one embodiment brings the need for actuation. Actuation can for example be achieved by means of a separate actuation mechanism. In some embodiments a self-sensing piezoelectric actuator can be used: a piezoelectric actuator employing the indirect piezoelectric effect can also be used as a piezoelectric sensor by employing the direct piezoelectric effect. In such embodiments a single piezoelectric transducer can be used for actuating the microstructure and for measuring its impedance and phase angle and thus for monitoring the resonance frequency.

In case of piezoelectric transducers, applying a DC potential can change the stiffness of the structure and can be used for tuning the resonance frequency. This brings another degree of freedom in device design and operation. A DC potential or bias inducing a resonance frequency change can also be used as a read-out mechanism, by monitoring the amount of DC bias required for a fixed resonance frequency (e.g. after analyte induced effects).

The second electronic transducer 3 shown in FIG. 1(a) and FIG. 1(b) is a piezoelectric transducer 3. However, also other transducers are possible as shown in FIG. 2, FIG. 3 and FIG. 4 in which the second transducer 3 respectively is a capacitive transducer, a magnetic transducer and a piezoresistive transducer. However, other transducers, although not shown, are also possible.

The second transducer 3 is substantially provided at the location of a local deformation 5 of the predetermined resonance mode, more specifically a single local deformation 5, to measure the deformation of the microresonator 1 at the location of the local deformation 5. Especially local deformations of resonance modes due to their shape featuring inhomogeneous deformation resulting in stress of opposite sign on the surface are detectable using the second transducer 3 at such a location. Also, as explained above, the location of the local deformation 5 preferably is a local extremum in deformation of the predetermined resonance mode. This is however not shown in the figures and the figures only show a schematic overview of the microresonator.

Although in FIG. 1, FIG. 2, FIG. 3 and FIG. 4, the first transducer 2 and the second transducer 3 are both similar and more in particular are both piezoelectric transducers (FIG. 1), both capacitive transducers (FIG. 2), both magnetic transducers (FIG. 3), or both piezoresistive transducers (FIG. 4), this is not critical for the invention and the first and the second transducer can be different and combinations of different types of transducers are possible such as for example a piezoelectric transducer with a capacitive transducer, magnetic transducer or a piezoresistive transducer.

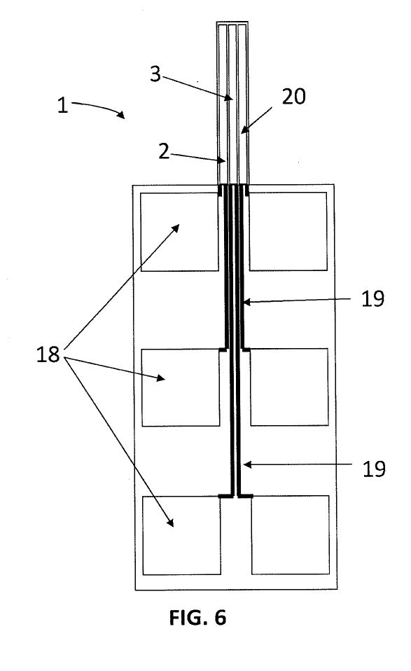

Although the figures show two transducers, this is not critical for the invention and also more transducers are possible to measure the deformation of the microresonator 1 at further locations. FIG. 6 for example shows a top view of a microcantilever 1 comprising three transducers 2, 3, 20. The transducers 2, 3, 20 extend adjacently and longitudinally along a length direction of the microcantilever 1. Such a configuration of the three transducers 2, 3, 20 is not critical for the invention and other configuration are possible.

Although the figures show a plurality of transducers, this is not critical for the invention and a single transducer 2 can be sufficient.

FIG. 1(c) further shows an example of the structure of a piezoelectric transducer. The piezoelectric transducer comprises a layer of piezoelectric material 7 sandwiched between two respective electrodes 8, 9. The electrodes are arranged such that electrical potential differences between the top surface of the piezoelectric layer 7 and the bottom of the piezoelectric layer 7 caused by strain in the piezoelectric layer, are transferred by respectively the top 8 and the bottom 9 electrodes such that they can be measured in order to establish the deformation of the microcantilever 1 at the first location, and in this case also the second location.

In one embodiment, the piezoelectric material is chosen from the group of ZnO, PZT (lead zirconate titanate or (Pb[ZrₓTi₁₋ₓ]O₃ with 0<x<1)) and AIN (aluminum nitride). However, any other type of suitable piezoelectric material known to the person skilled in the art can be used.

FIG. 1(b) shows a top view of the microcantilever 1 of FIG. 1(a) and shows the position of the first transducer 2 and the second transducer 3 in more detail. It can be seen that the first transducer 2 is positioned near the location 27 where the beam 16 of the cantilever is clamped. The second transducer 3 is positioned nearer the tip 17 of the beam 16. The measuring electrodes of both transducers 2, 3 are connected to bond pads 18 through conductive pathways 19.

FIG. 2 shows a microcantilever 1 in which both transducers 2, 3 are capacitive transducers. The capacitive transducers 2, 3 shown in FIG. 2 are made by applying a first electrode 11 on the surface 6 of the microresonator 1 and applying a second electrode 12 with respect to the first electrode 11 such that deformation of the microresonator 1 at the location of the first electrode 11 changes the distance between the first 11 and the second 12 electrode and therefore the capacitance between the first 11 and the second 12 electrode such that an electric signal representing the deformation of the microresonator 1 at the location of the first electrode 11 can be measured.

FIG. 3 shows a microcantilever 1 in which both transducers 2, 3 are magnetic transducers. The transducers 2, 3 comprise a pair of magnetic material 13 and a magnetic detector 14 for detecting the magnetic field emitted by the magnetic material. The magnetic transducers 2, 3 shown in FIG. 3 can for example be made by applying a thin film permanent magnet 13, magnetic material, along the surface 6 of the microcantilever 1 and providing a magnetic sensor 14, such as for example a coil or a giant magnetoresistance device, a colossal magnetoresistance device, a magnetic tunnel junction, or any kind of device that responds to the changes in the magnetic field, the magnetic sensor 14 being placed with respect to the thin film permanent magnet 13 such that deformation of the microresonator 1 at the location of the thin film permanent magnet 13 changes the distance between the thin film permanent magnet 13 and the magnetic sensor 14 and therefore the magnetic field measured by the magnetic sensor 14 such that an electric signal representing the deformation of the microresonator 1 at the location of the thin film permanent magnet 13 can be measured. However, although not shown, the magnetic sensor can also be applied along the surface 6 of the microresonator 1 and the thin film permanent magnet away from the microresonator 1. However, it has been found that the thin film permanent magnet 13 is more easily applied along the surface of the microresonator 1 than a magnetic sensor such as for example a coil. A variable magnetic field can be used for actuating the microresonator.

FIG. 4 shows a microcantilever 1 in which both transducers 2, 3 are piezoresistive; more in particular the transducers 2, 3 comprise a piezoresistive wire 15 along the surface 6 of the microcantilever 1. The piezoresistive wire 15 is arranged such that a deformation of the microresonator 1 at the location of the piezoresistive wire 15 causes a measurable electrical signal, e.g. a resistance change of the piezoresistive wire 15. The microcantilever can be actuated by providing electric current pulses to the transducers. Although it is shown as wires on the resonator, any possible material and device configuration that changes its resistance with strain can be used as a piezoresistive transducer.

The transducers 2, 3 shown in FIG. 1 and FIG. 4 have the advantage that substantially the whole transducer 2, 3 is integrated with the microresonator 1 resulting in a compact microcantilever 1 whereas the transducers 2, 3 shown in FIG. 2 and FIG. 3 require an additional part (counterpart) next to the part located along the surface 6 of the microresonator 1.

One or more than one of the transducers integrated with the resonator can be used for tuning and/or changing one or more of the resonance frequencies by for example changing the moment of inertia of the resonator (e.g. changing the curvature of a resonating beam); by generating axial load (tensile or compressive) for a clamped-clamped or membrane type resonator; by changing the local stiffness for example locally manipulating the temperature of a particular area of the resonator; by applying an auxiliary force on the resonator by electrostatic or electromagnetic methods or by any other means of manipulating one or more of the resonance frequencies of the resonator.

FIG. 5 shows an overview of some different shaped microresonators 1. The different microresonators comprise a different shape such as for example rectangular, possibly in different dimensions (FIG. 5(a) and FIG. 5(c)), triangular (FIG. 5(f)), etc. A protrusion 10 such as for example an extended tip (FIG. 5(b)), a hammerhead design (FIG. 5(d) and FIG. 5(e)), etc. or a point mass, a functional area that causes cross sectional and/or geometrical irregularity can be used for increasing the amplitude of local deformations at a given resonance mode, etc.

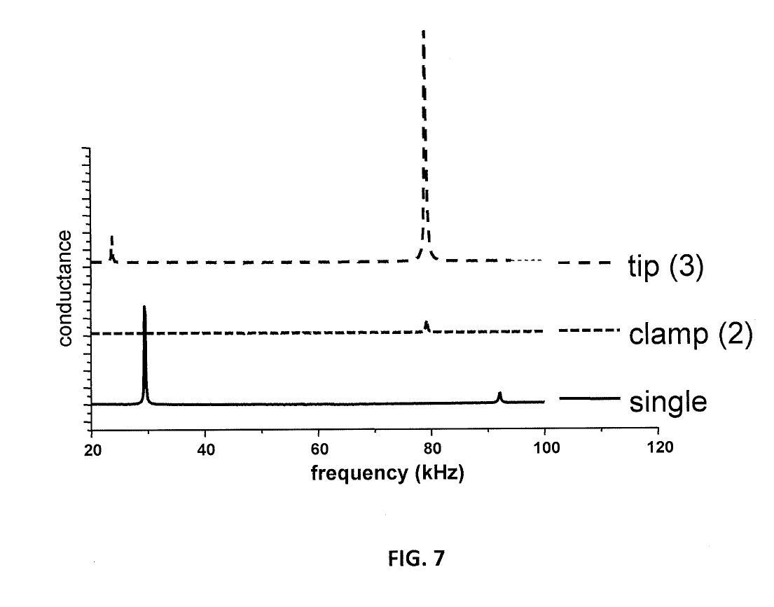

FIG. 7 shows the impedance spectrum (full line) of a microcantilever comprising a rectangular beam with a single piezoelectric transducer covering the whole surface of the microcantilever beam. FIG. 7 also shows the impedance spectrum (dashed lines) for a microcantilever according to one embodiment, the microcantilever comprising a rectangular beam with two piezoelectric transducers, a first transducer 2 being provided near the clamped side 27 of the microcantilever, and a second transducer 3 being provided near the tip (free side) 17 of the microcantilever (as illustrated in FIG. 1(b)). In the examples shown, the width of the microcantilever beams was 143 micrometer and the length 400 micrometer. An analysis was performed with an impedance analyzer, with a small signal voltage of 50 mV. As can be seen in FIG. 7, the different piezoelectric transducers have a significantly different impedance response to different resonance modes.

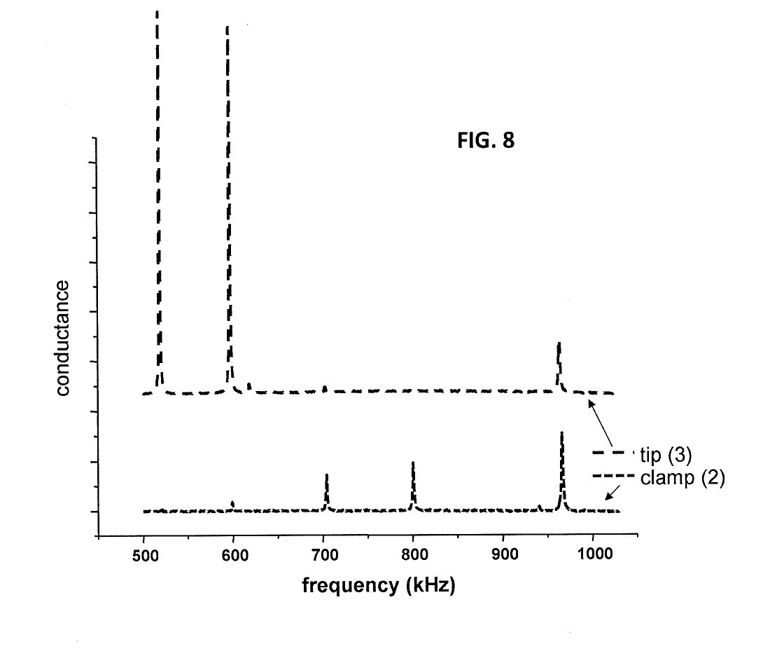

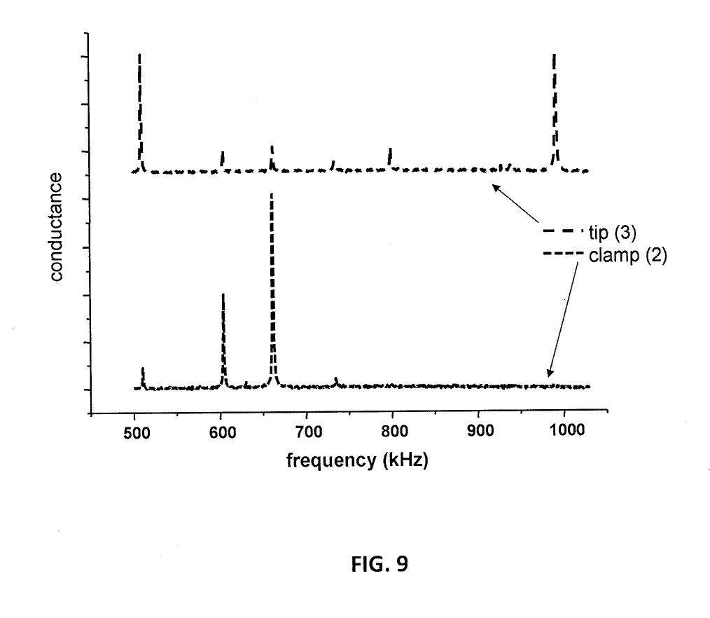

A similar behavior was observed for various beam dimensions and for different transducer configurations. For example, FIG. 8 shows impedance spectra for a configuration wherein the first piezoelectric transducer 2 (near the clamped side 27) covers one third of the microcantilever length and wherein the remaining part of the microcantilever is covered by the second piezoelectric transducer 3 (near the tip 17 of the microcantilever). The first transducer 2 shows no or a very small signal for the frequency range between 500 kHz and 600 kHz, whereas the second transducer 3 has two resonance peaks in that frequency range with Q values larger than 500. FIG. 9 shows impedance spectra for a configuration wherein the first piezoelectric transducer 2 covers half of the microcantilever length and wherein the remaining part of the microcantilever is covered by the second piezoelectric transducer 3. Clear differences for the frequency range between 500 kHz and 600 kHz can be observed as compared to the results shown in FIG. 8. The difference of the impedance spectra shows how different transducer configurations can be exploited for resonance sensing applications. For a preferred high order resonance mode a transducer can be assigned for capturing a high quality signal.

One embodiment relates to a resonator sensor comprising a microresonator 1 as described above.

One embodiment relates to a sensor array comprising at least two microresonators as described above, each of the microresonators 1 having different resonance modes due to, for example, different shapes (rectangular, triangular, etc.), different extended tips, hammerhead designs, point masses, functional areas, tapered and reversely tapered shapes, etc.

Using different geometries, particularly for cantilevers (single clamped beams in general), can help in resolving surface stress induced resonance frequency shifts. Different geometries lead to a different clamping behavior of the cantilevers. For example, cantilevers with the same surface area (hence the same mass change in analyte exposure in a sensor application) but with different clamping can be used. For example a triangular (or tapered) cantilever does have a larger clamping zone compared to a rectangular one with the same surface area. This creates a difference in terms of the effect of surface stress and makes it easier to resolve surface stress induced resonance frequency shift.

One embodiment relates to a method for making a microresonator 1 as described above comprising analyzing at least one resonance mode of a microresonator 1, finding at least one location of the microresonator 1 comprising a local deformation 4, 5 of the analyzed resonance mode and providing an electronic transducer integrated with the microresonator 1 for measuring deformation of the microresonator 1 at the location. The local deformation of the analyzed resonance mode can for example be found using optical methods or finite elements calculating methods.

In one embodiment, analyzing the at least one resonance mode of the microresonator is done by, for example, in a first block making a model of the microresonator and calculating the resonance modes, for example using finite elements. In a next block a model is for example made of the microresonator with a transducer applied on the location of the local deformation after which the resonance modes are again calculated, for example using finite elements, to determine the influence of the presence of the transducer. This process can be repeated until the transducer is located at the desired location for measuring deformation of the microresonator 1 at the location of a local deformation 4, 5 which preferably is at the location of a local extremum of the microresonator with the integrated transducer. The process of analyzing the at least one resonance mode of the microresonator can in other words be seen as an iterative process.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention.

What is claimed is:

1. A microresonator device for use as a resonator in a detector, the device comprising:
a microresonator configured to resonate in a first predetermined resonance mode, the first predetermined resonance mode being one of higher order resonance modes; and
an integrated electronic transducer configured to measure deformation of the microresonator in the first predetermined resonance mode, wherein the transducer is provided at the location of a local deformation of the predetermined resonance mode to measure the deformation of the microresonator at the location of the local deformation.

2. The device according to claim 1, wherein the first and/or second local deformation is a local extremum in deformation of the predetermined resonance mode.

3. The device according to claim 1, wherein the device comprises a second integrated electronic transducer configured to measure deformation of the microresonator in a second predetermined resonance mode of the microresonator, the second transducer being provided at the location of a second different local deformation of the second predetermined resonance mode to measure the deformation of the microresonator at the location of the second local deformation.

4. The device according to claim 3, wherein the second predetermined resonance mode is of a lower order than the first predetermined resonance mode.

5. The device according to claim 3, wherein the second predetermined resonance mode equals the first predetermined resonance mode.

6. The device according to claim 1, wherein the transducer comprises a layer of piezoelectric material sandwiched between two respective measuring electrodes.

7. The device according to claim 6, wherein the piezoelectric material is chosen from the group of ZnO, PZT (lead zirconate titanate or (Pb[ZrₓTi₁₋ₓ]O₃ with 0<x<1)) and AIN (aluminium nitride).

8. The device according to claim 1, wherein the transducer is a magnetic transducer.

9. The device according to claim 1, wherein the transducer is a capacitive transducer.

10. The device according to claim 1, wherein the microresonator comprises a protrusion extending from the remainder of the microresonator that causes cross sectional and/or geometrical irregularity for promoting the amplitude of local deformations at a given resonance mode.

11. The device according to claim 1, wherein the microresonator is a microcantilever.

12. A resonator sensor comprising a microresonator device according to claim 1.

13. A sensor array comprising at least two microresonator devices according to claim 1, each of all microresonator devices having different resonance modes.

14. A method of making a microresonator device, the method comprising:
analyzing at least one resonance mode of a microresonator;
finding at least one location at the surface of the microresonator comprising a local deformation of the analyzed resonance mode; and
integrating an electronic transducer configured to measure deformation of the microresonator at the location.

15. The method of making a microresonator device according to claim 14, wherein the local deformation is a local extremum.

16. The method of making a microresonator device according to claim 14, wherein the at least one resonance mode is one of higher order resonance modes.

17. The method of making a microresonator device according to claim 14, wherein the transducer comprises a layer of piezoelectric material sandwiched between two respective measuring electrodes.

18. The method of making a microresonator device according to claim 14, wherein the microresonator is a microcantilever.

19. A device for use as a resonator in a detector, the device comprising:
means for resonating in a first predetermined resonance mode, the first predetermined resonance mode being one of higher order resonance modes; and
means for measuring deformation of the resonating means in the first predetermined resonance mode, wherein the measuring means is provided at the location of a local deformation of the predetermined resonance mode to measure the deformation of the resonating means at the location of the local deformation.

20. The device according to claim 19, wherein the measuring means is integrated with the resonating means.
